(19) United States
(12) Patent Application Publication
(10) Pub. No.: US 2014/0153315 A1
(43) Pub. Date: Jun. 5, 2014

(54) SEMICONDUCTOR MEMORY APPARATUS, REFRESH METHOD AND SYSTEM

(71) Applicant: RESEARCH & BUSINESS FOUNDATION SUNGKYUNKWAN UNIVERSITY, Suwon-si (KR)

(72) Inventors: Keewon KWON, Seongnam-si (KR); Jongmin BAEK, Jeollabuk-do (KR); Dongjin SEO, Gwangju (KR)

(73) Assignee: RESEARCH & BUSINESS FOUNDATION SUNGKYUNKWAN UNIVERSITY, Suwon-si (KR)

(21) Appl. No.: 14/095,269

(22) Filed: Dec. 3, 2013

(30) Foreign Application Priority Data
Dec. 4, 2012 (KR) 10-2012-0139735

(51) Int. Cl. G11C 13/00

(52) U.S. Cl. CPC G11C 13/0033
USPC 365/148

(57) ABSTRACT

Disclosed are a semiconductor memory apparatus, and refresh method and system. The semiconductor memory apparatus includes: a memory cell array including a plurality of resistive memory cells; and a control block configured to control at least one of a mode and a schedule of a refresh operation for the plurality of memory cells to be variable based on digital code values reflecting resistance states of the plurality of resistive memory cells. Therefore, the refresh of the resistive memory is efficiently performed, and as a result, performance deterioration may be minimized, and a lifespan of the device may be extended.

This application claims the benefit of priority of Korean Patent Application No. 10-2012-0139735 filed on Dec. 4, 2012, which is incorporated by reference in its entirety herein.

### BACKGROUND OF THE INVENTION

1. Field of the Invention

The present invention relates to a semiconductor apparatus, and a refresh method and system, and more particularly, to a semiconductor apparatus, and refresh method and system based on distribution control of a ReRAM memory.

2. Discussion of the Related Art

Recently, as devices have rapidly been small-sized, there is difficulty due to limitation of the number of charges stored in a nonvolatile memory based on the charges including a flash memory. From the viewpoint, a resistive random access memory (ReRAM) has been in the limelight as a replacement memory for overcoming the difficulty due to refinement. However, the ReRAM is a nonvolatile memory having a characteristic in which a resistance of a cell is variable by a voltage or a current applied to the cell, and has advantages of having a large margin for sensing data and having a relatively fast speed and low power consumption as compared with other nonvolatile memories. However, in the case of a normal ReRAM, reliability and a lifespan of device are generally good, but device characteristics deteriorate due to interference by an extra voltage and environment factors (particularly, a resistance change by heat). For example, in the case where a reading or write operation continuously occurs, a resistance is changed by a stress due to joule heating. Further, when a predetermined period elapses without the reading/write operation, the characteristic as the nonvolatile memory is lost due to various environment factors and the interference, and in this case, the device lifespan has a different value for each chip.

FIGS. 1A and 1B are diagrams for describing a refreshing method after the read operation according to a change in resistance distribution of a cell and a cell state by repeating the read operation illustrated in the U.S. Pat. No. 8,107,277 B2 (issued in Jan. 31, 2012) of Kabushiki Kaisha Toshiba. Referring to FIG. 1A, the initial resistances of the memory cell read as “0” and “1” have different resistance states from an original reference resistance due to the distribution broken after performing the read operation repeated at a high voltage pulse. In thus case, the distribution of the memory cell having the state value of “1” deteriorates more than that of the memory cell having the state value of “0”.

Referring to FIG. 1B, when the state value does not reach a predetermined target value during a read verify process after the read operation of the ReRAM, rewriting (refresh operation) is performed by applying a pulse voltage to the cell, and as a result, the distribution becomes narrow.

In the related art, in order to perform the refresh operation, the read operation needs to be preceded, and when viewing the memory operation in terms of a system, most of cells maintain an idle (or precharge) state for a most of time without the read (or write) operation, and in this state, receive interference due to a change in external environment, and a resistance change occurs. Furthermore, when adjacent cells continuously operate, the cell in the idle state losses the initial resistance due to the interference and the stress. In this case, although the read operation does not precede, the refresh operation needs to be performed, and as a result, the cell operates without an error. Further, since the change of the resistance due to the interference varies for each cell, entirely, it is inefficient to perform the refresh operation.

### SUMMARY OF THE INVENTION

In order to solve the above-mentioned problems, an object of the present invention provides a semiconductor memory apparatus, and refresh method and system that controls a refresh to be efficiently performed by minimizing deterioration of performance of a resistive memory, extending a device lifespan, and monitoring a resistance for each cell.

In accordance with an embodiment of the present invention, a semiconductor memory apparatus, including: a memory cell array including a plurality of resistive memory cells; and a control block configured to control at least one of a mode and a schedule of a refresh operation for the plurality of memory cells to be variable based on digital code values reflecting resistance states of the plurality of resistive memory cells.

The control block may control a first refresh mode and a second refresh mode to be performed by classifying a first and a second level by comparing a bit value of the digital code value with a reference value and grouping the plurality of memory cells.

The control block may classify a memory cell among the plurality of memory cells, in which a degree in which a resistance state deviates from a target value is smaller than a predetermined threshold value, into a first level by comparing the bit value of the digital code value with the reference value, and classify a memory cell among the plurality of memory cells, in which a degree in which a resistance state deviates from a target value is larger than a predetermined threshold value, into a second level by comparing the bit value of the digital code value with the reference value.

The first refresh mode associated with the resistive memory cell of the first level may be a mode in which a hidden refresh is performed with respect to each resistive memory cell in an idle state, and the second refresh mode associated with the resistive memory cell of the second level may be a mode in which the refresh is compulsively performed with respect to the entire memory while blocking a system access.

When the control block performs an incremental step pulse programming (ISPP) mode during the refresh process, the control block may control the resistive memory cell of the first level to perform the ISPP mode while sequentially increasing a voltage magnitude or a voltage applying time based on a predetermined initial voltage magnitude or initial voltage applying time, and control the resistive memory cell of the second level to perform the ISPP mode while applying the initial voltage magnitude or the initial voltage applying time which is larger or longer than the resistive memory cell of the first level.

The control block may control the refresh operation to be performed with respect to all the plurality of resistive memory cells based on a power-up operation or a periodically monitoring operation, or the refresh operation to be performed for each corresponding cell by monitoring resistance states of the plurality of resistive memory cells every read operation.

The control block may control at least one of an applying voltage magnitude and a voltage applying time for the plurality of resistive memory cells to be variable during the refresh operation with respect to the plurality of resistive memory cells based on the digital code value.

The semiconductor memory apparatus may further include an analog to digital converter (ADC) configured to generate the digital code value.

The control block may classify one state value (including SET (1) or RESET (0)) of the plurality of resistive memory cells into at least two levels based on the digital code value, and allocates refresh schedules of the plurality of resistive memory cells to be different from each other.

A built-in-self-test (BIST) for monitoring the plurality of resistive memory cells may be used.

When the plurality of memory cells connected to one word line simultaneously performs the write operation by sharing one power line, the control block may control magnitudes of the initial voltages applied through the bit lines to vary according to the digital code value while the initial applying voltages through the word lines are the same as each other during the refresh operation with respect to the plurality of memory cells connected to one word line.

In accordance with another embodiment of the present invention, a refresh method of a semiconductor memory apparatus includes: generating a digital code value reflecting resistance states of a plurality of resistive memory cells; and controlling at least one of a mode and a schedule of a refresh operation to be variable with respect to the plurality of resistive memory cells based on the generated digital code value.

The controlling may include controlling a first refresh mode and a second refresh mode to be performed by classifying a first and a second level by comparing a bit value of the digital code value with a reference value and grouping the plurality of memory cells.

The controlling may include classifying a memory cell among the plurality of memory cells, in which a degree in which a resistance state deviates from a target value is smaller than a predetermined threshold value, into a first level by comparing the bit value of the digital code value with the reference value, and classifying a memory cell among the plurality of memory cells, in which a degree in which a resistance state deviates from a target value is larger than a predetermined threshold value, into a second level by comparing the bit value of the digital code value with the reference value.

The first refresh mode associated with the resistive memory cell of the first level may be a mode in which a hidden refresh is performed with respect to each resistive memory cell in an idle state, and the second refresh mode associated with the resistive memory cell of the second level may be a mode in which the refresh is compulsively performed with respect to the entire memory while blocking a system access.

When performing an incremental step pulse programming (ISPP) mode during the refresh process, the controlling may include controlling the resistive memory cell of the first level to perform the ISPP mode while sequentially increasing a voltage magnitude or a voltage applying time based on a predetermined initial voltage magnitude or initial voltage applying time, and controlling the resistive memory cell of the second level to perform the ISPP mode while applying the initial voltage magnitude or the initial voltage applying time which is larger or longer than the resistive memory cell of the first level.

A built-in-self-test (BIST) for monitoring the plurality of resistive memory cells may be used.

When the plurality of memory cells connected to one word line simultaneously performs the write operation by sharing one power line, the controlling may include controlling magnitudes of the initial voltages applied through the bit lines to be variable according to the digital code value while the initial applying voltages through the word lines are the same as each other in the ISPP mode with respect to the plurality of memory cells.

In accordance with yet another embodiment of the present invention, a semiconductor memory system includes: a semiconductor memory apparatus; and a processor for controlling a write operation and a verify read operation of the semiconductor memory apparatus, in which the semiconductor memory apparatus includes a memory cell array including a plurality of resistive memory cells; and a control block configured to control at least one of a mode and a schedule of a refresh operation for the plurality of memory cells to be variable based on digital code values reflecting resistance states of the plurality of resistive memory cells.

The control block may control a first refresh mode and a second refresh mode to be performed by classifying a first and a second level by comparing a bit value of the digital code value with a reference value and grouping the plurality of memory cells.

The first refresh mode associated with the resistive memory cell of the first level may be a mode in which a hidden refresh is performed with respect to each resistive memory cell in an idle state, and the second refresh mode associated with the resistive memory cell of the second level may be a mode in which the refresh is compulsively performed with respect to the entire memory while blocking a system access.

According to the semiconductor memory apparatus, and the refresh method and system of the present invention, the refresh of the resistive memory is efficiently performed to minimize performance deterioration and extend a lifespan of the device, and the refresh is efficiently performed by monitoring a resistance for each memory cell to prevent interference occurring during a multi-write (or program).

### BRIEF DESCRIPTION OF THE DRAWINGS

FIGS. 1A and 1B are diagrams for describing a refresh performing method after a read operation according to a change in resistance distribution by repeating the read operation and a cell state.

FIG. 2 is a diagram illustrating deterioration of a current characteristic of a resistive cell according to a read cycle repetition.

FIG. 3 is a schematic diagram for describing classifying cell states by using an ADC of the semiconductor memory apparatus according to the embodiment of the present invention.

FIG. 4 is a diagram illustrating a configuration of the semiconductor memory apparatus according to the embodiment of the present invention.

FIG. 5 is a block diagram for describing controlling an initial voltage magnitude or an initial voltage applying time based on a digital code value of the semiconductor memory apparatus according to the embodiment of the present invention.

FIG. 6 is a diagram illustrating a circuit diagram and a timing diagram for describing an operation of a word line (WL) driver of the semiconductor memory apparatus according to the embodiment of the present invention.

FIG. 7 is a flowchart illustrating a process until a refresh operation is performed by monitoring deterioration of a cell characteristic of the semiconductor memory apparatus according to the embodiment of the present invention.

FIG. 8 is a conceptual diagram for describing a refresh operation performed in order to improve deterioration of an initial current characteristic by a repeated reading/write operation of the semiconductor memory apparatus according to the embodiment of the present invention.

FIG. 9 is a diagram illustrating a form in which a magnitude of an initial applying voltage varies in an ISPP mode when a write operation is performed based on a digital code value according to a cell characteristic by the semiconductor memory apparatus according to the embodiment of the present invention.

FIG. 10 is a diagram illustrating a form in which an initial voltage applying time varies in an ISPP mode when a write operation is performed based on a digital code value according to a cell characteristic by the semiconductor memory apparatus according to the embodiment of the present invention.

FIG. 11 is a schematic block diagram of a semiconductor memory system according to an embodiment of the present invention.

FIG. 12 is a diagram for describing a layout of multi power lines of a semiconductor memory apparatus according to another embodiment of the present invention.

FIG. 13 is a diagram illustrating a form in which a magnitude of an initial applying voltage varies in an ISPP mode when a write operation is performed based on a digital code value according to a cell characteristic by the semiconductor memory apparatus according to the embodiment of the present invention.

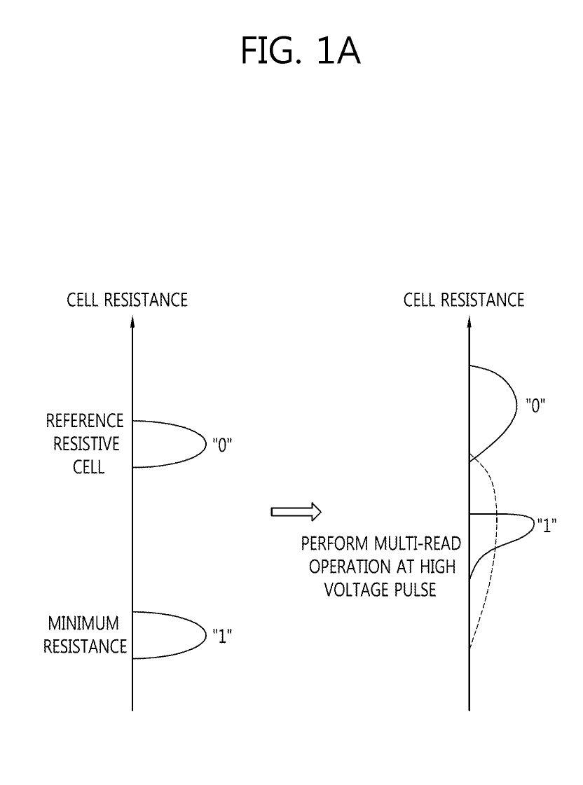

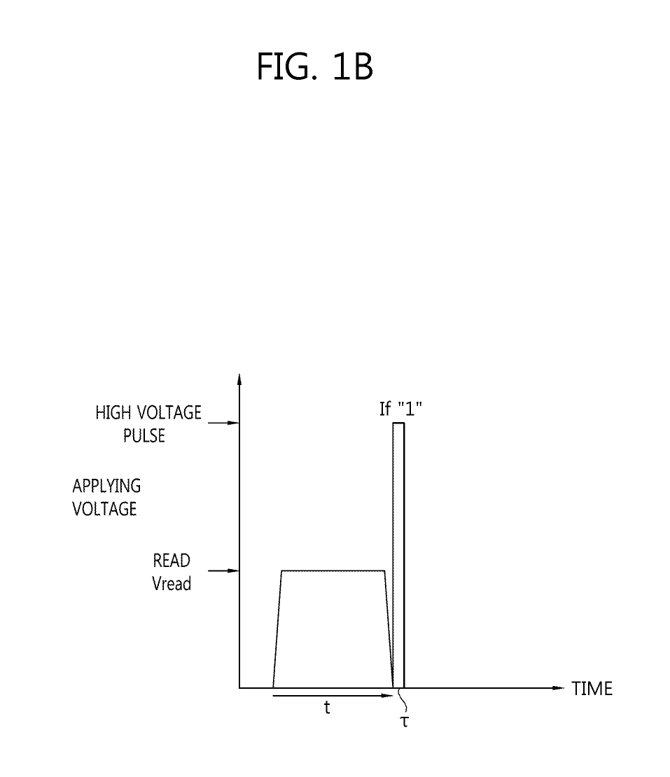

### DETAILED DESCRIPTION OF THE EMBODIMENTS

The present invention may have various modifications and various exemplary embodiments and specific exemplary embodiments will be illustrated in the drawings and described in detail.

However, this does not limit the present invention within specific exemplary embodiments, and it should be understood that the present invention covers all the modifications, equivalents and replacements within the idea and technical scope of the present invention.

Terms such as first or second may be used to describe various components but the components are not limited by the above terminologies. The above terminologies are used only to discriminate one component from the other component. For example, without departing from the scope of the present invention, a first component may be referred to as a second component, and similarly, a second component may be referred to as a first component. A terminology such as and/or includes a combination of a plurality of associated items or any item of the plurality of associated items.

It should be understood that, when it is described that an element is “coupled” or “connected” to another element, the element may be “directly coupled” or “directly connected” to the another element or “coupled” or “connected” to the another element through a third element. In contrast, it should be understood that, when it is described that an element is “directly coupled” or “directly connected” to another element, it is understood that no element is not present between the element and the another element.

Terms used in the present application are used only to describe specific exemplary embodiments, and are not intended to limit the present invention. A singular form may include a plural form if there is no clearly opposite meaning in the context. In the present application, it should be understood that term “include” indicates that a feature, a number, a step, an operation, a component, a part or the combination thereof described in the specification is present, but does not exclude a possibility of presence or addition of one or more other features, numbers, steps, operations, components, parts or combinations, in advance.

If it is not contrarily defined, all terms used herein including technological or scientific terms have the same meaning as those generally understood by a person with ordinary skill in the art. Terms which are defined in a generally used dictionary should be interpreted to have the same meaning as the meaning in the context of the related art but are not interpreted as an ideally or excessively formal meaning if it is not clearly defined in the present invention.

Hereinafter, a preferable embodiment of the present invention will be described in more detail with reference to the accompanying drawings. In describing the present invention, like reference numerals refer to like elements for easy overall understanding and a duplicated description of like elements will be omitted.

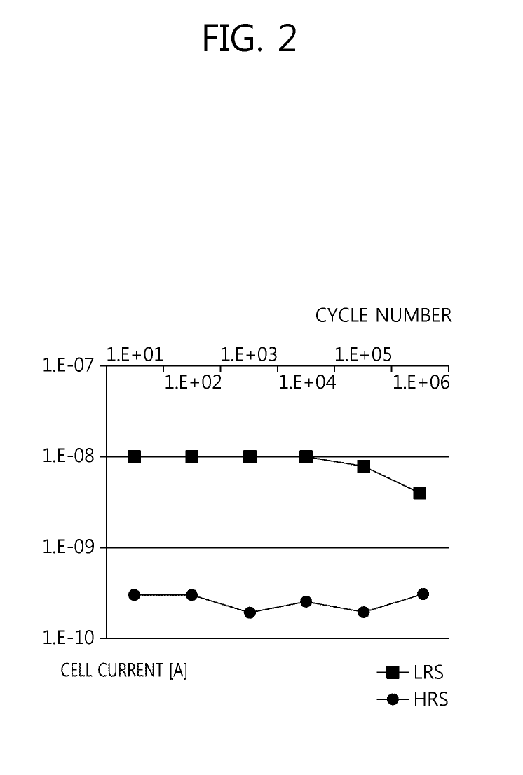

FIG. 2 is a diagram illustrating deterioration of a current characteristic of a resistive cell according to a read cycle repetition. As illustrated in FIG. 2, when one resistive cell is repetitively read, a cell current characteristic deteriorates according to a reading number. In FIG. 2, a case where a lot of current flow (that is, a case where resistance is small (low resistance state (LRS))) is defined as a set state, and a case where a little of current flows (that is, a case resistance is large (high resistance state (HRS))) is defined as a reset state. A set (1) and a reset (0) may be defined as state values. In this case, in the case of a stable cell operation, even though the reading number is increased, a predetermined current value needs to be maintained, and in the case of a resistive memory, when the reading number is repeated, the resistive memory has a characteristic (particularly, largely represented in the LRS) in which an initial used resistance is slightly changed by an effect due to Joule Heating. The characteristic deterioration shows a difference tendency for each cell, and in the case of the worst cell, a sensing error occurs much faster than another cell. Accordingly, a device lifespan is determined by the worst cell. According to the embodiment of the present invention, since the characteristic deterioration due to interference and stress varies for each cell, the characteristic may be controlled cell by cell.

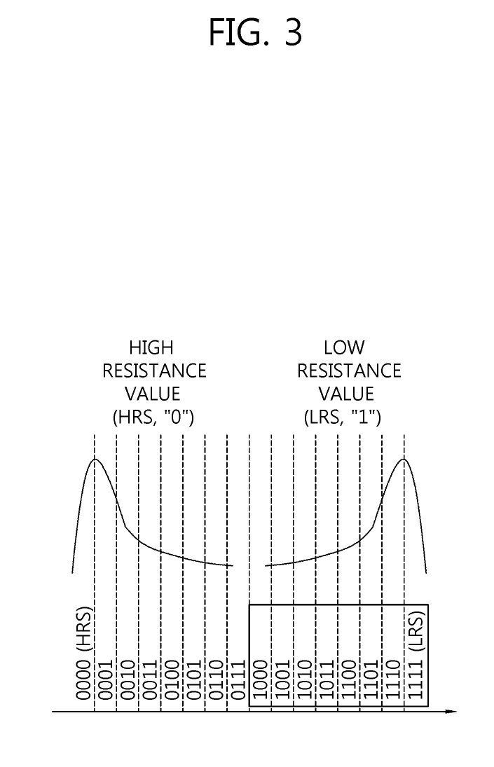

FIG. 3 is a diagram for describing expressing a state according to a resistance as a digital code value in the semiconductor memory apparatus according to the embodiment of the present invention. As illustrated in FIG. 3, the same set (1) is converted into the digital code value to display “1” of various states. That is, the same “1” may be divided into levels from 1000 to 1111 through various digital code values within the state values. In this case, the respective digital code values displayed as “1” represent resistance distribution of the memory cell, and a refresh operation (or other various operation modes) may be performed differently according to the digital code value.

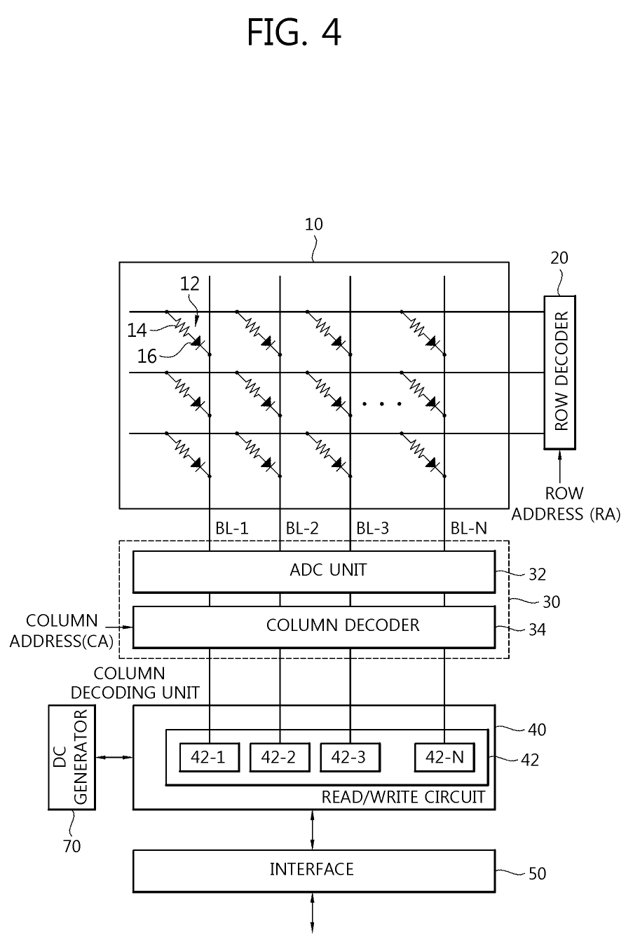

FIG. 4 is a diagram schematically illustrating a configuration of the semiconductor memory apparatus according to the embodiment of the present invention. As illustrated in FIG. 4, a semiconductor memory apparatus may include a memory cell array 10, a row decoder 20, a column decoder 30, a control block 40, an interface 50, and a DC generator 70.

The memory cell array 10 may include a plurality of bit lines BL1 to BLN, a plurality of word lines WL1, WL2, WL3, . . . , and a plurality of resistive memory cells 12.

The plurality of resistive memory cells 12 each uses a resistance of a resistive memory element 14 in order to store one bit or one or more bits of data. For example, a resistive memory element 14 programmed to have a high resistance may express a logic “0” data bit value, and a resistive memory element 14 programmed to have a low resistance may express a logic “1” data bit value.

The plurality of resistive memory cells 12 each may include a resistive memory element 14 and an access device 16 for controlling a current flowing in the resistive memory element 14. According to the embodiment of the present invention, the resistive memory element 14 is called a memory cell or a memory material.

Further, the plurality of resistive memory cells 12 each may be implemented as a ReRAM, a phase change random access memory (PRAM), or a flash memory. The PRAM called a PCRAM or an ovonic unified memory (OUM) may use a phase change material for the resistive memory element 14.

Further, the resistive memory element 14 may be implemented by phase change materials having different resistances according a crystalline state or an amorphous state.

The access device 16 is called an isolation device, and may be implemented as a diode-type, an MOSFET-type, or a BJT-type. In the drawing, a diode-type access device 16 is illustrated, but the present invention is not necessarily limited thereto.

The row decoder 20 decodes a row address (RA) to select at least one word line (or one row) among the plurality of word lines WL1, WL2, WL3, . . . . The column decoder 34 decodes a column address (CA) to select at least one bit line (or column) among the plurality of bit lines BL1 to BLn.

The column decoder 30 includes an ADC unit 32 and a column decoder 34. The ADC unit 32 may include a plurality of ADCs. The ADC unit 32 reflects a resistance state of the resistive array cell 12 to generate a digital code value. That is, the ADC unit 32 monitors the resistance states of the plurality of resistive memory cells 12 to generate a predetermined bit number of digital code value depending on a deviant degree of the resistance states of the plurality of resistive memory cells as compared with a target value. For example, one ADC is disposed for every eight bit lines to sense a current flowing in the bit line connected with the memory cell 12 by a unit of eight resistive memory cells 12 and generate a predetermined bit number of digital code value. The generated digital code value is provided to the control block 40.

In the case where a characteristic (for example, a resistance) of the resistive memory element 14 is changed according to continuous read/write operations, the control block 40 controls program data (or write data) to repetitively perform a write operation (or program operation) and a verification read operation based on the digital code value associated with the resistance of the resistive memory cell 12 received from the ADC unit 30, while increasing a program (or write) voltage applying time (or a program time, a pulse duration) in the resistive memory cell 12.

Here, the write operation (or program operation, write operation) means an operation of making a resistance of the resistive memory element 14 of the resistive memory cell 12 to a high resistance or a low resistance by supplying a voltage pulse or a current pulse to the resistive memory cell 12.

The refresh operation may be performed by a similar method to the aforementioned write operation. That is, the refresh operation means an operation of making a desired high resistance or low resistance by applying a voltage pulse (refresh pulse (expressed as a writing power voltage in some cases)) based on a resistance state of the resistive memory element 14.

The control block 40 may include a read/write circuit 42. Alternatively, the read/write circuit 42 may also be configured by a separate block which is not included in the control block 40. The control block 40 may control a DC generator 70 controlling an initial voltage magnitude and/or an initial voltage applying time. For example, the DC generator 70 may generate a pulse signal V_{WR} of which the initial voltage magnitude and/or the initial voltage applying time (a pulse duration or a pulse width) of the write operation and/or the refresh operation increases, in order to compensate for a deviation degree from the initial resistance as the number of read operations and/or program operations (for example, resetting operations) increases.

Further, the DC generator 70 may generate a pulse signal V_{WR} in which both the initial voltage applying time and the initial voltage magnitude increase, in order to compensate for a deviation degree from the initial resistance as the number of read operations and/or program operations (for example, resetting operations) increases.

The control block 40 according to the embodiment of the present invention uses a scheme in which at least one of a refresh and/or program time and a refresh and/or program voltage increases as the number of reading and/or program operations increases or as a loop of a read and/or program cycle is repeated, in order to control threshold voltage distribution or resistance distribution. Further, the control block 40 according to the embodiment of the present invention may control at least one of a refresh mode and a refresh schedule for each memory cell 12 to be variable during the refresh operation according to the resistance distribution (that is, according to the digital code value). Here, the refresh schedule may mean a time when the refresh operation is performed. Further, the refresh schedule includes an intensity and a duration of the refresh operation, that is, a magnitude of a refresh voltage and an applying time of the refresh voltage. The control block 40 may control a refresh performing time so that the refresh operation immediately occurs according to a digital code value, and in some cases, may also control the refresh performing time so that the refresh operation occurs at a short interval of time.

Accordingly, the control block 40 according to the embodiment of the present invention applies an incremental step pulse programming (ISPP) scheme to the refresh time in the refresh operation, or applies the ISPP scheme to both the refresh time and the refresh voltage.

The interface 60 performs serves to transmit and receive program data (or writing data) or reading data between the control block 40 and a host (not illustrated).

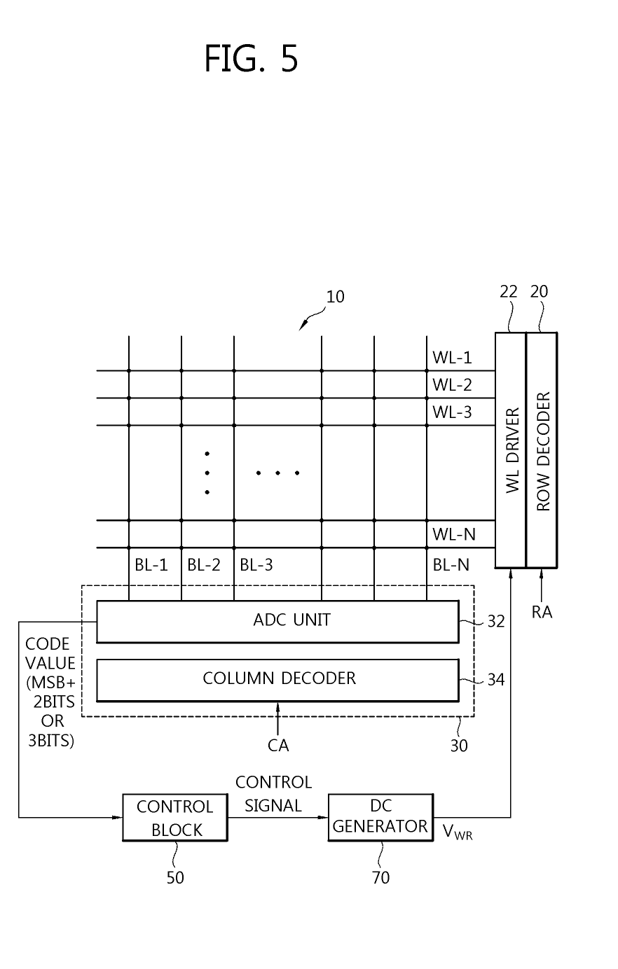

FIG. 5 is a block diagram for describing controlling an initial voltage magnitude or an initial voltage applying time in an ISPP mode during a refresh operation based on a digital code value of the semiconductor memory apparatus according to the embodiment of the present invention. As illustrated in FIG. 5, the semiconductor memory apparatus may include a memory cell array 10, a row decoder 20, a word line (WL) driver 22, an ADC unit 32, a column decoder 34, a control block 50, and a DC generator 70.

Referring to FIG. 5, a resistance of each memory cell 12 of the memory cell array 10 is sensed in the ADC unit 32 to be converted into a digital code value.

The row decoder 20 decodes the row address RA to select at least one of a plurality of word lines WL-1 to WL-N of the memory cell array 10, as described above. The word line driver 22 drives the word lines WL-1 to WL-N selected by supplying a power voltage V_{WR} which is an output of the DC generator 70.

The ADC unit 32 is connected with the bit lines BL-1 to BL-N of the memory cell array 10 to sense a current value output through the bit lines BL-1 to BL-N and generate a digital code value. According to an embodiment of the present invention, a state according to the resistance of the memory cell 12 may be expressed as, for example, a digital code value of 4 bits or 3 bits by using a 4-bit ADC 32 or a 3-bit ADC 32 instead of a bit line sense amplifier (BLSA) in the related art. However, it is not necessarily limited to the 4 bits or 3 bits, and a digital code value having a different bit length value may be used.

A most significant bit (MSB) of the generated 3-bit or 4-bit digital code value may be used as a state value. The state value means a state value LRS or HRS including a SET (1) or a RESET (0). The state value means a binary value stored in an actual memory cell as a state value.

The rest of two or three lower bits except for the most significant bit value from the 3-bit or 4-bit digital code value is provided to the control block 50.

The control block 50 may classifying the state value of the resistive memory cell 12 into at least two levels based on the rest of the bit values except for the most significant bit. That is, one state value may be subdivided into several levels again, and the control block 50 may control a proper refresh voltage to be applied to each memory cell 12 by applying different initial applying voltages or voltage applying times according to the subdivided levels. The control block 50 provides a control signal associated with voltage applying for a specific memory cell 12 to the DC generator 70.

The DC generator 70 applies the voltage applied to the resistive memory cell 10 to the driver 22. The driver 22 receives a voltage from the DC generator 70 to apply the received voltage to the corresponding resistive memory cell 12.

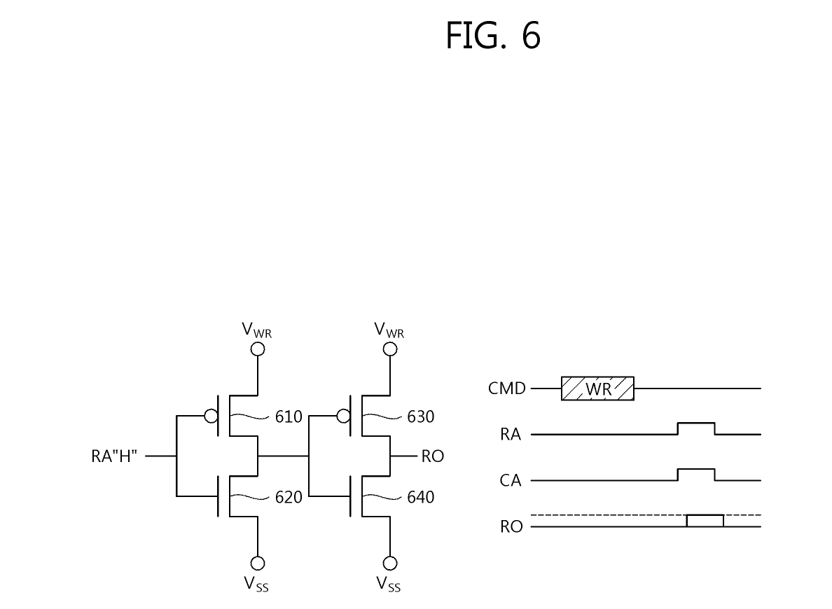

FIG. 6 is a diagram illustrating a circuit diagram and a timing diagram for describing an operation of the word line (WL) driver 22 of the semiconductor memory apparatus according to the embodiment of the present invention. As illustrated in FIG. 6, the WL driver 22 includes a plurality of transistors 610, 620, 630, and 640.

As illustrated in a circuit diagram of the left WL driver of FIG. 6, a first PMOS transistor 610 is connected to a first NMOS transistor 620 in series. Further, a second PMOS transistor 630 is connected to a second NMOS transistor 640 in series. First, when a high H signal is input to the row address RA, the first PMOS transistor 610 is turned off and the first NMOS transistor 620 is turned on, and then when a Vss signal is provided to a gate of the second PMOS transistor 630, the second PMOS transistor 630 is turned on and the second NMOS transistor 640 is turned off, and as a result, a writing power voltage V_{WR} is output to the RO. In this way, the WL driver 22 applies the corresponding power voltage V_{WR} for refresh to each memory cell 12 based on the decoded row address.

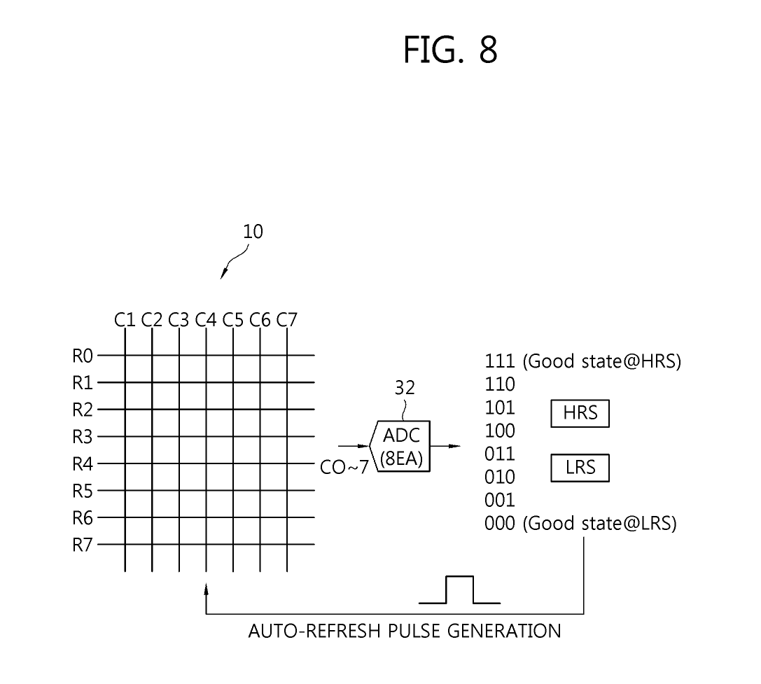

Referring to a right timing diagram of FIG. 6, after a writing WR command CMD signal is activated, a row address RA and a column address CA are applied, and a refresh power voltage V_{WR} is applied to the RO (R0 among R0 to R7 of FIG. 8) which is a word line corresponding to the decoded word line of the WL driver 22.

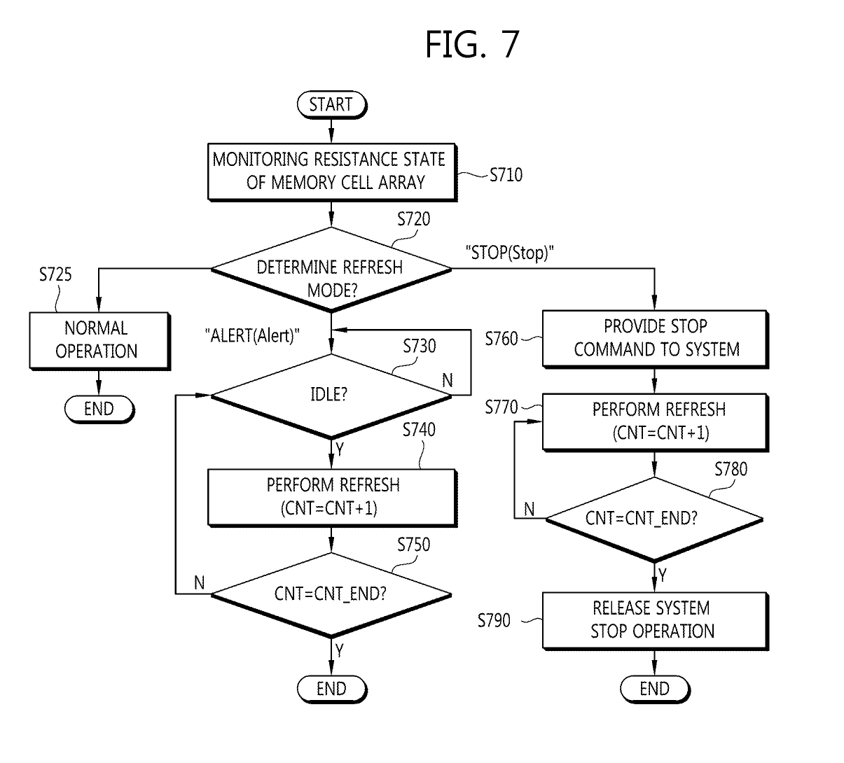

FIG. 7 is a flowchart illustrating a process until a refresh operation is performed by monitoring deterioration of a cell characteristic of the semiconductor memory apparatus according to the embodiment of the present invention.

Referring to FIG. 7, the semiconductor memory apparatus monitors the resistance state of the memory cell array 10 in order to determine a degree of the deterioration of the cell characteristic (S710). When the resistive memory has a non-volatile memory characteristic, but when a predetermined time (life time) elapses after performing the writing in a specific cell, the resistive memory loses the characteristic as the memory even though there is no access. Particularly, the characteristic deterioration is significantly shown at a high temperature. Further, since an operation environment varies for each chip, there is no choice but to have different life-spans. Therefore, according to the embodiment of the present invention, a read operation of a test array may be performed in order to periodically check a state of the entire chip every power-up or once a day by implementing a BIST circuit in the chip. In this case, the test array exists in an idle state where no operation is performed outside a BIST time performed during power up (or in a test pattern performing state if necessary). Accordingly, the characteristic of the test array may be monitored every power-up or at regular intervals. However, only the monitoring for the test array is not necessarily performed, but the monitoring for the memory cell array 10 other than the test array is performed to perform the refresh. In addition, as the monitoring result, when a digital code value by the ADC 32 is decreased to a predetermined value or less, the refresh is performed, and a mode during the refreshing is determined (S720). In this case, it is determined whether the cell characteristic is an “alert” level or a “stop” level which is more serious than the “alert” level. The above levels may be classified by comparing a bit value of the digital code value through the monitoring with a reference value. For example, the “alert” level means a case where a degree in which the resistance state of the memory cell 12 deviates from a target value based on the digital code value is smaller than a threshold value, and the “stop” level means a case where the degree in which the resistance state of the memory cell 12 deviates from the target value based on the digital code value is larger than the threshold value. For example, when the level of each memory cell 12 is classified based on the 3-bit digital code value, 111 is a normal state in which there is no need to refresh, and 110 as an alert level and 101 as a stop level may be classified, respectively. In this case, when the memory cell 12 shows a normal resistance state, a normal operation may be performed without the refresh operation (S725).

As the determined result of the refresh mode, in the case of the “alert” mode, it is determined whether the memory cell 12 determined as the “alert” mode is in an idle mode at present (S730). In the case of the idle mode, the refresh is sequentially performed in the memory cells 12 (S740). In addition, when the refresh is completed up to the last memory cell 12 (S750), the refresh operation is completed. That is, in the alert mode, a hidden refresh operation is sequentially performed with respect to the memory cells 12.

As the determined result of the refresh mode, in the case of the “stop” mode, that is, in the case of the resistance state which is more serious than the “alert” mode, all the chips are refreshed by creating a flag. In this case, in order to avoid corrosion with a command in a system, a stop command is provided to the system (S760). In addition, regardless of the existence of the idle mode, all the chips sequentially perform the refresh operation (S770). When the refresh operation is completed up to the last memory cell 12 (S780), the stop operation of the system is released in order to restore the system again (S790). That is, a command of operating the system again is provided.

FIG. 8 is a conceptual diagram for describing a refresh operation performed in order to improve deterioration of an initial current characteristic by a repeated reading/write operation of the semiconductor memory apparatus according to the embodiment of the present invention.

Referring to FIG. 8, R0 to R7 represent word lines, and C0 to C7 represent bit lines. A difference from the resistive memory sensing in the related art uses the ADC 32, and electric characteristics may be classified according to a cell by using the ADC 32, and the refresh may be performed according to the generated digital code value. In the case of the low resistance state (LRS), most of normal cells have values of 111. However, weak cells or cells having a lot of interference have values lower than 111. Accordingly, the refresh operation may be variably performed if necessary by subdividing the state value of “1” or “0” into the digital code values.

Referring to FIG. 8, the semiconductor memory apparatus of the present invention uses the ADC 32 in the reading process in order to efficiently perform the write operation. A state LRS:1 or HRS:0 of the memory cells 12 may be divided into eight digital codes by using the ADC 32. For example, the digital code value is determined according to a current value flowing in the bit line connected with the memory cell 12, and the ADC 32 may set to generate a digital code value of 000 when the current value is 100 nA, and to generate a digital code value of 111 when the current value is 1 uA. The reason is that a range of the current read according to a resistance change in the ReRAM is almost 100 nA to 1 uA. The setting may be controlled by coding through a user interface. It is assumed that a 3-bit ADC 32 is used, and in some cases, 2 bits to several bits of ADC 32 may be used.

As illustrated in FIG. 8, since the resistance state of the memory cell is sensed through the ADC 32 during the read operation, the semiconductor memory apparatus according to the present invention may read a state value corresponding to SET (LRS “1”) or RESET (HRS “0”) as the most significant bit (MSB) value of the digital code value. In this case, the rest of two bit values except for the most significant bit represent the resistance distribution of the resistive memory cells 12. Accordingly, in the SET or RESET process of the reading process, if the resistance is not sufficiently increased up to 111 or 000, a stress such as a refresh pulse is increased to make 111 or 000.

According to an embodiment of the present invention, one state value may be divided into various levels according to a digital code value. In this case, the levels may be the same as or different from the above level classification of the “alert” mode and the “stop” mode. That is, the state value may be divided into various levels by using a reference value different from the reference value that divides the “alert” mode and the “stop” mode. Further, when briefly describing the operation for the memory cell 12 of the low resistance state, when 100/101 code is generated while sending the resistive memory cell 12, the refresh operation is automatically performed by a flag created by the 100/101 code after performing the read operation. A fail cell due to the characteristic deterioration may be created to a cell having a normal characteristic by applying a refresh pulse, and the device lifespan is increased. As another example, when the refresh operation is not continuously performed after reading verification, but performed in the idle state, the refresh operation may be performed without the characteristic deterioration of the system. The embodiment of the present invention may vary the writing voltage or the voltage applying time during the refresh operation according to a characteristic (digital code value) of the memory cell 12.

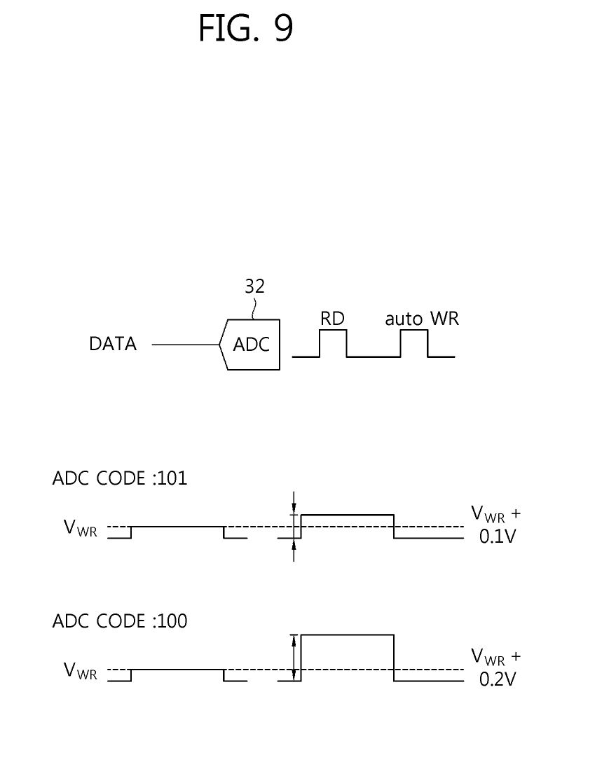

FIG. 9 is a diagram illustrating a form in which a magnitude of an initial applying voltage varies when a refresh operation is performed based on a digital code value according to a cell characteristic by the semiconductor memory apparatus according to the embodiment of the present invention. The upper drawing of FIG. 9 illustrates that the refresh operation is performed according to a digital code value by reading and auto-writing control signals after the data signal passes through the ADC 32.

Two lower graphs of FIG. 9 are examples of the refresh operation according to a digital code value, and initial voltages having different magnitudes are generated according to a digital code value during the refresh operation. For example, since the memory cells 12 of the first level having the digital code of 101 have small resistances to be corrected (Soft weak cell), a voltage higher than a refresh voltage for a normal cell by 0.1 V is applied in the early stages. Similarly, since the memory cell 12 having the digital code of 101 has a worse cell characteristic than the memory cell 10 of the first level (Hard weak cell), the memory cell 12 has the largest initial voltage step magnitude when the refresh operation is performed. Particularly, in the case of the worst cell having the digital code value of 100, a maximum voltage is applied in comparison with a voltage applied to another memory cell 12 and where there is no response even in repetitive applications at a reference number of times or more, the worst cell is defined as a hare fail and thus may be excluded.

According to the embodiment of the present invention, when incremental step pulse programming (ISPP) is applied in the refresh process, the level classification according to a digital code value is performed, and the initial applying voltage and/or the initial voltage applying time may vary according to the classified level. That is, the resistive memory cell 12 of the first level may control the ISPP mode to be perform while sequentially increasing a voltage magnitude or a voltage applying time based on a predetermined initial voltage magnitude or initial voltage applying time, and the resistive memory cell 12 of the second level controls the ISPP mode to be performed while applying the initial voltage magnitude or the initial voltage applying time which is larger or longer than the resistive memory cell of the first level. As such, even in the case of the worst cell, since the incremental step of the ISPP may be minimized, the refresh time may be reduced, and further, unnecessary current consumption may be reduced.

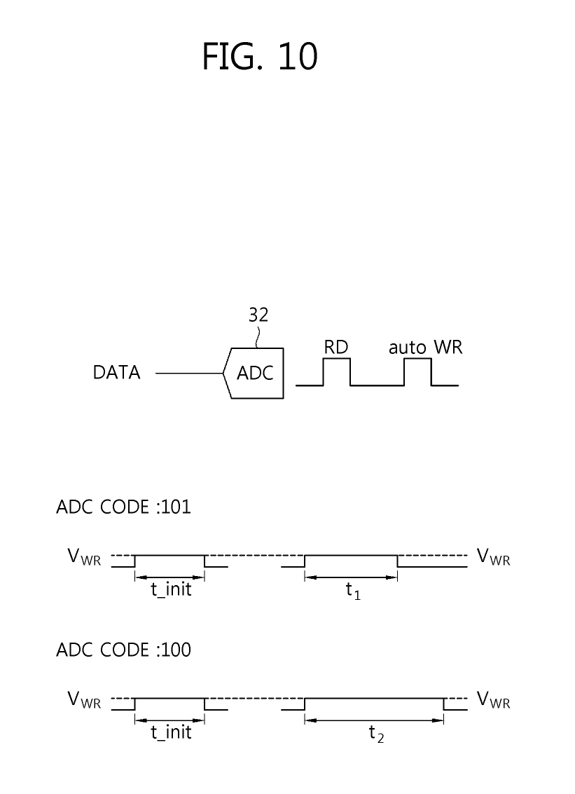

FIG. 10 is a diagram illustrating a form in which an initial voltage applying time varies when a refresh operation is performed based on a digital code value according to a cell characteristic by the semiconductor memory apparatus according to the embodiment of the present invention. In the resistive memory, the resistance is changed according to a voltage applying number (or time) due to a characteristic of the resistance. That is, in the case of the HRS, when a lot of pulses are input, the resistance is gradually increased and eventually saturated. Such a phenomenon may be applied equally even to a case where the pulse is input for a long time. That is, in the case of the HRS, when the voltage is input for a long time, the resistance is increased. Accordingly, a resistance change according to the voltage applying time may be applied to the refresh operation.

Referring to FIG. 10, according to another embodiment of the present invention, the initial voltage applying time may vary according to a cell characteristic when performing the refresh operation based on the digital code value. For example, since the memory cells 12 of the first level having the digital code value of 101 have small resistances to be corrected (Soft weak cell), the memory cells 12 may initially apply the voltage for a predetermined voltage applying time t₁. Since the 100 (the second level) has a relatively bad cell characteristic (Hard weak cell), an initial voltage applying time t₂ is increased during the refresh operation. In the case of the worst cell, a maximum voltage which is larger than the first level is applied and repetitively applied by the reference number, and when there is no response, the cell is defined as a hard fail and may be excluded.

Even in the embodiment in which the refresh operation is performed by controlling the initial voltage applying time, a voltage applying time varies according to a cell characteristic, and as a result, the number of ISPP steps may be reduced, thereby efficiently restoring a desired resistance.

According to yet another embodiment of the present invention, the magnitude of the initial applying voltage and the applying time may be simultaneously controlled according to a cell state when the refresh operation is performed (combination of FIGS. 9 and 10).

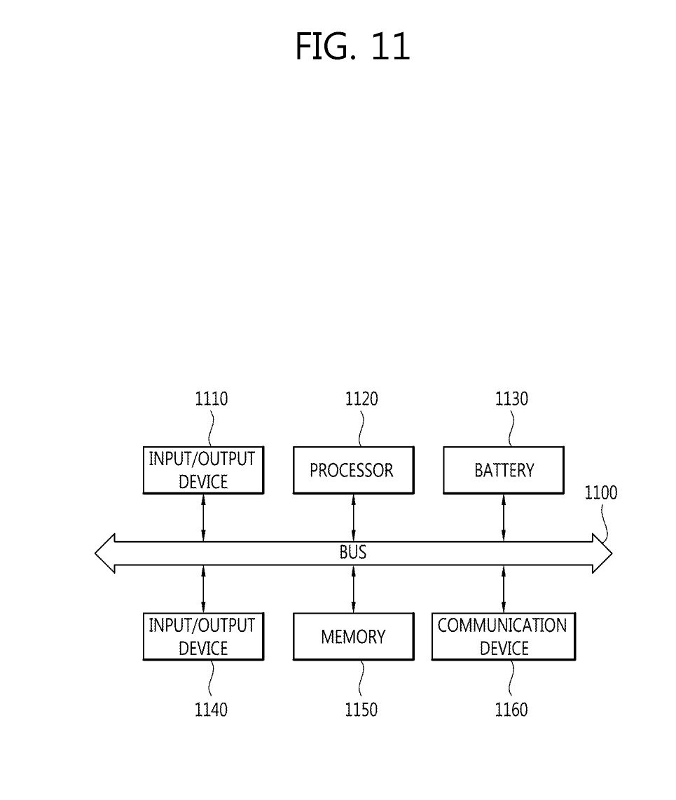

FIG. 11 is a schematic block diagram of a semiconductor memory system according to an embodiment of the present invention. A semiconductor memory system such as a computer includes a memory apparatus 1150 connected to a system bus 1100, and a processor 1120.

The processor 1120 may entirely control a write operation, a read operation, or a verify read operation of the memory apparatus 1150. For example, the processor 1120 outputs a command for controlling the write operation of the memory apparatus 1150, and writing data. Further, the processor 1120 may generate a command for controlling the read operation or the verify read operation of the memory apparatus 1150. Accordingly, the control block 40 of the semiconductor memory apparatus 1150 may perform the verify read operation or the program operation (or the write operation) in response to a control signal (for example, an nPRG, a DIS, a WEN, or a REN) output from the processor 1120. The control block 40 of the semiconductor memory apparatus 1150 may perform the refresh operation in response to the control signal from the processor 1120.

In the case where the semiconductor memory system is implemented as a portable application, the semiconductor memory system may further include a battery 1130 for supplying operation power to the memory apparatus 1150 and the processor 1120.

The portable application may include a portable computer, a digital camera, personal digital assistants (PDA), a cellular phone, an MP3 player, a portable multimedia player (PMP), an automotive navigation system, a memory card, a smart card, a game machine, an electronic dictionary, or a solid state disc.

The semiconductor system may further include an interface for transmitting and receiving data to and from an external data processing device, for example, input/output devices 1110 and 1140.

In the case where the semiconductor system is a wireless system, the semiconductor system may further include a memory apparatus 1150, a processor 1120, and a communication device 1160. In this case, the communication device 1160 is connected to the processor 1120 as a wireless interface and may wirelessly transmit and receive the data to and from an external wireless device (not illustrated) through the system bus 1100.

For example, the processor 1120 processes the data input through the communication device 1160 to store the processed data in the memory apparatus 1150, and further, the data stored in the memory apparatus 1150 may be read to be transmitted to the wireless interface 1160.

The wireless system including the communication device 1160 may be a wireless device such as a PDA, a portable computer, a wireless telephone, a pager, and a digital camera, an RFID reader, or an RFID system. Further, the wireless system may be a wireless local area network system or a wireless personal area network (WPAN) system. Further, the wireless system may be a cellular network.

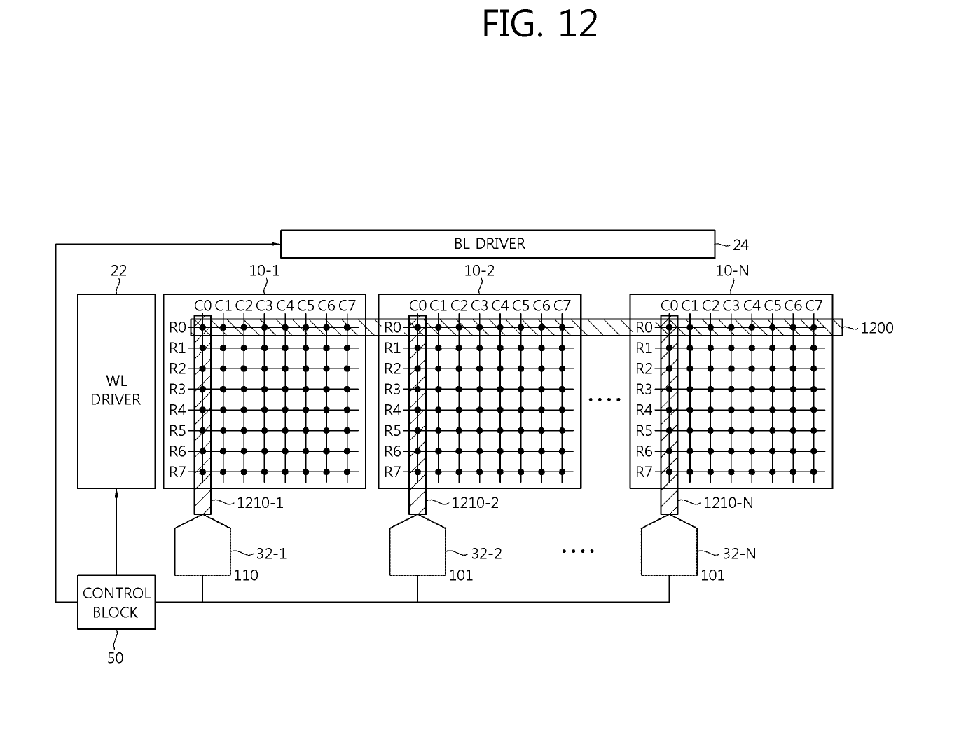

FIG. 12 is a diagram for describing a layout of multi power lines of a semiconductor memory apparatus according to another embodiment of the present invention. As illustrated in FIG. 12, the semiconductor memory apparatus according to the embodiment of the present invention include a word line driver 22 and a bit line driver 24 in order to apply a voltage allocated to each memory cell 10 when the refresh operation is performed according to a multi-write operation.

Referring to FIG. 12, the memory cells 10-1, 10-2, . . . , 10-N may be formed in a plurality of matrixes. One memory cell matrix 10-1, 10-2, . . . , 10-N may be configured by eight columns and eight rows. The multi-write operation means performing the write operation by several k byte unit by sharing a power line in which the voltage is applied to the plurality of memory cell matrixes 10-1, 10-2, . . . , 10-N. In this case, when the initial word line voltage varies according to a cell characteristic during the refresh operation, a target word line voltage value varies every cell, and as a result, there is a problem in the case of sharing the word line.

According to the embodiment of the present invention, the semiconductor memory apparatus acquires the resistance state of each memory cell 12 through ADCs 32-1, 32-2, . . . , 32-N, and may control the initial applying voltage of the refresh operation in response to the resistance state of the memory cell 12. Particularly, when the plurality of memory cells 12 connected to one word line share one power line 1200, the voltage for each memory cell 12 may be controlled by the bit line driver 24 during the refresh operation. The semiconductor memory apparatus according to the embodiment of the present invention acquires the resistance state for each memory cell 12 because the respective ADCs 32-1, 32-2, . . . , 32-N are connected to the respective bit lines 1210-1, 1210-2, . . . , 1210-N, and provides the acquired resistance state information to a control block 50. The control block 50 controls a predetermined initial applying voltage to be provided to the memory cell 12 through the word line driver 22 like the exiting refresh operation, and controls different initial applying voltages to be provided for each memory cell 12 according to the resistance state information acquired through the bit line driver 24. That is, the initial applying voltage of the refresh operation provided through the bit line driver 24 may be variable in response to the resistance state of each memory cell 12.

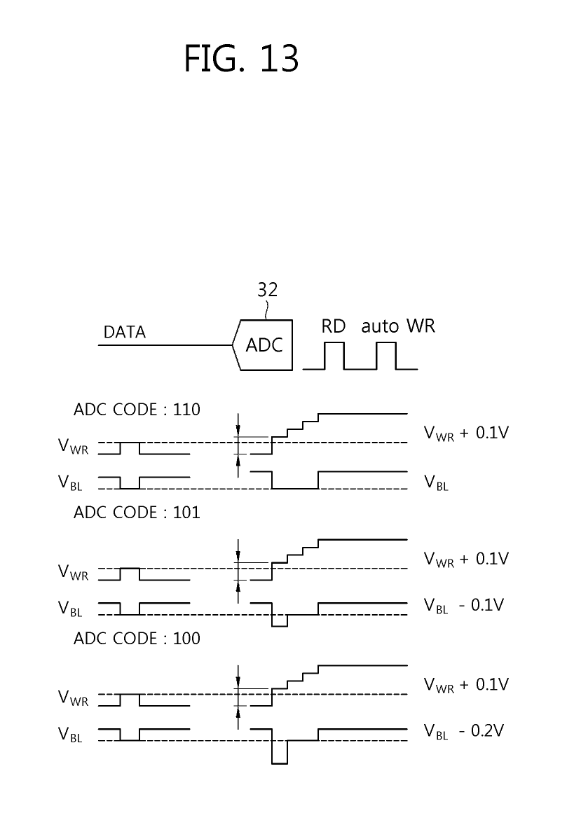

FIG. 13 is a diagram illustrating a form in which a magnitude of the initial applying voltage provided through the bit line varies when a refresh operation is performed based on a digital code value according to a cell characteristic by the semiconductor memory apparatus according to the embodiment of the present invention. An upper drawing of FIG. 13 illustrates that a read and verify control signal is converted into a digital code value through the ADC 32.

Three lower graphs of FIG. 13 are examples of the refresh operation according to the digital code value, and the initial applying voltages provided through the word lines during the refresh operation according to the digital code value are the same as each other, but the voltages provided through the bit lines generate initial voltages having different magnitudes. For example, since the memory cells 12 of the level having the digital code value of 110 have small resistances to be corrected (Soft weak cell), a refresh voltage is provided through the word line to be higher than a refresh voltage V_{WR} for the memory cell 12 having the digital code value of 111 by a predetermined level, and the same refresh voltage as the related art may be provided through the bit line. In addition, since the 101 has a relatively worse cell characteristic than the memory cell 12 of the level corresponding to 110 (Hard weak cell), the voltage provided through the word line during the refresh operation is the same as that in the case of 110, but the voltage provided through the bit line has a relatively large initial voltage step magnitude (here, the magnitude means an absolute value of the voltage) (in the embodiment, V_{BL}-0.1V). Similarly, since the 100 corresponds to the worse cell (Soft fail cell), the word line voltages are the same as each other during the refresh operation, but the initial voltage step magnitude provided through the bit line becomes largest (in the embodiment, V_{BA}-0.2V). Particularly, in the case of the worst cell having the digital code value of 100, a maximum voltage is applied through the bit line and when there is no response even in repetitive applications at a reference number of times or more, the worst cell is defined as a hare fail and thus may be excluded.

While the invention has been shown and described with respect to the preferred embodiments, it will be understood by those skilled in the art that various changes and modifications may be made without departing from the spirit and scope of the invention as defined in the following claims.

What is claimed is:

1. A semiconductor memory apparatus, comprising:
a memory cell array including a plurality of resistive memory cells; and
a control block configured to control at least one of a mode and a schedule of a refresh operation for the plurality of memory cells to be variable based on digital code values reflecting resistance states of the plurality of resistive memory cells.

2. The semiconductor memory apparatus of claim 1, wherein:
the control block controls a first refresh mode and a second refresh mode to be performed by classifying a first and a second level by comparing a bit value of the digital code value with a reference value and grouping the plurality of memory cells.

3. The semiconductor memory apparatus of claim 2, wherein:
the control block classifies a memory cell among the plurality of memory cells, in which a degree in which a resistance state deviates from a target value is smaller than a predetermined threshold value, into a first level by comparing the bit value of the digital code value with the reference value, and
classifies a memory cell among the plurality of memory cells, in which a degree in which a resistance state deviates from a target value is larger than a predetermined threshold value, into a second level by comparing the bit value of the digital code value with the reference value.

4. The semiconductor memory apparatus of claim 2, wherein:
the first refresh mode associated with the resistive memory cell of the first level is a mode in which a hidden refresh is performed with respect to each resistive memory cell in an idle state, and
the second refresh mode associated with the resistive memory cell of the second level is a mode in which the refresh is compulsively performed with respect to the entire memory while blocking a system access.

5. The semiconductor memory apparatus of claim 2, wherein:
when the control block performs an incremental step pulse programming (ISPP) mode during the refresh process,
the control block controls the resistive memory cell of the first level to perform the ISPP mode while sequentially increasing a voltage magnitude or a voltage applying time based on a predetermined initial voltage magnitude or initial voltage applying time, and
controls the resistive memory cell of the second level to perform the ISPP mode while applying the initial voltage magnitude or the initial voltage applying time which is larger or longer than the resistive memory cell of the first level.

6. The semiconductor memory apparatus of claim 1, wherein:
the control block controls the refresh operation to be performed with respect to all the plurality of resistive memory cells based on a power-up operation or a periodically monitoring operation, or the refresh operation to be performed for each corresponding cell by monitoring resistance states of the plurality of resistive memory cells every read operation.

7. The semiconductor memory apparatus of claim 1, wherein:
the control block controls at least one of an applying voltage magnitude and a voltage applying time for the plurality of resistive memory cells to be variable during the refresh operation with respect to the plurality of resistive memory cells based on the digital code value.

8. The semiconductor memory apparatus of claim 1, further comprising:
an analog to digital converter (ADC) configured to generate the digital code value.

9. The semiconductor memory apparatus of claim 1, wherein:
the control block classifies one state value (including SET (1) or RESET (0)) of the plurality of resistive memory cells into at least two levels based on the digital code value, and allocates refresh schedules of the plurality of resistive memory cells to be different from each other.

10. The semiconductor memory apparatus of claim 1, wherein:
a built-in-self-test (BIST) for monitoring the plurality of resistive memory cells is used.

11. The semiconductor memory apparatus of claim 1, wherein:
when the plurality of memory cells connected to one word line simultaneously performs the write operation by sharing one power line, the control block controls magnitudes of the initial voltages applied through the bit lines to vary according to the digital code value while the initial applying voltages through the word lines are the same as each other during the refresh operation with respect to the plurality of memory cells connected to one word line.

12. A refresh method of a semiconductor memory apparatus, comprising:
generating a digital code value reflecting resistance states of a plurality of resistive memory cells; and
controlling at least one of a mode and a schedule of a refresh operation to be variable with respect to the plurality of resistive memory cells based on the generated digital code value.

13. The refresh method of a semiconductor memory apparatus of claim 12, wherein:
the controlling includes controlling a first refresh mode and a second refresh mode to be performed by classifying a first and a second level by comparing a bit value of the digital code value with a reference value and grouping the plurality of memory cells.

14. The refresh method of a semiconductor memory apparatus of claim 13, wherein:
the controlling includes classifying a memory cell among the plurality of memory cells, in which a degree in which a resistance state deviates from a target value is smaller than a predetermined threshold value, into a first level by comparing the bit value of the digital code value with the reference value, and
classifying a memory cell among the plurality of memory cells, in which a degree in which a resistance state deviates from a target value is larger than a predetermined threshold value, into a second level by comparing the bit value of the digital code value with the reference value.

15. The refresh method of a semiconductor memory apparatus of claim 13, wherein:
the first refresh mode associated with the resistive memory cell of the first level is a mode in which a hidden refresh is performed with respect to each resistive memory cell in an idle state, and
the second refresh mode associated with the resistive memory cell of the second level is a mode in which the refresh is compulsively performed with respect to the entire memory while blocking a system access.

16. The refresh method of a semiconductor memory apparatus of claim 13, wherein:
the controlling includes when performing an incremental step pulse programming (ISPP) mode during the refresh process,
controlling the resistive memory cell of the first level to perform the ISPP mode while sequentially increasing a voltage magnitude or a voltage applying time based on a predetermined initial voltage magnitude or initial voltage applying time, and
controlling the resistive memory cell of the second level to perform the ISPP mode while applying the initial voltage magnitude or the initial voltage applying time which is larger or longer than the resistive memory cell of the first level.

17. The refresh method of a semiconductor memory apparatus of claim 12, wherein:
a built-in-self-test (GIST) for monitoring the plurality of resistive memory cells is used.

18. The refresh method of a semiconductor memory apparatus of claim 12, wherein:
the controlling includes when the plurality of memory cells connected to one word line simultaneously performs the write operation by sharing one power line,
controlling magnitudes of the initial voltages applied through the bit lines to be variable according to the digital code value while the initial applying voltages through the word lines are the same as each other in the ISPP mode with respect to the plurality of memory cells.

19. A semiconductor memory system, comprising:
a semiconductor memory apparatus; and
a processor for controlling a write operation and a verify read operation of the semiconductor memory apparatus,
wherein the semiconductor memory apparatus includes
a memory cell array including a plurality of resistive memory cells; and
a control block configured to control at least one of a mode and a schedule of a refresh operation for the plurality of memory cells to be variable based on digital code values reflecting resistance states of the plurality of resistive memory cells.

20. The semiconductor memory system of claim 19, wherein:
the control block controls a first refresh mode and a second refresh mode to be performed by classifying a first and a second level by comparing a bit value of the digital code value with a reference value and grouping the plurality of memory cells.
